(19) United States
(12) Patent Application Publication
(10) Pub. No.: US 2009/0009953 A1
(43) Pub. Date: Jan. 8, 2009

(54) PORTABLE HARD DISK DRIVE WITH PIVOTABLE SUPPORT LEGS

(75) Inventor: Mei-Feng LIN, Taipei (TW)

Correspondence Address: RABIN & Berdo, PC, 1101 14TH STREET, NW, SUITE 500, WASHINGTON, DC, 20005, US

(73) Assignee: JOU JYE ELECTRONIC CO., LTD, Taipei City (TW)

(21) Appl. No.: 11/773,767

(22) Filed: Jul. 5, 2007

(51) Int. Cl. H05K 7/00; H05K 5/00; G06F 1/16

(52) U.S. Cl. 361/685

(57) ABSTRACT

A portable hard disk drive with pivotable support legs includes a disk enclosure having a built-in hard disk drive and being formed from two case members connected via an upper and a lower connecting strip, respectively; two support legs in the form of two curved panels separately mounted to an outer side of a lower part of each of the two case members via a torsional spring and a pivot shaft, the torsional springs providing elastic force to pivotally turn the two support legs outward from the lower parts of the two case members to an extended position; and a push button assembly provided on the lower connecting strip to normally hold the two support legs to a closed position. When the push button assembly is pushed, the two support legs are outward pushed by the torsional springs to the extended position, allowing the whole disk enclosure to stand upright.

### FIELD OF THE INVENTION

The present invention relates to a portable hard disk drive (HDD), and more particularly to a portable HDD having two support legs connected to outer sides of two case members thereof to be pivotally turned between a closed position and an extended position via two torsional springs a push button assembly. When the support legs are turned to the extended position, the whole portable HDD may stably stand upright.

### BACKGROUND OF THE INVENTION

Generally, a personal computer uses a built-in hard disk as a storage device thereof. Since the hard disk is able to store a large quantity of data, people are allowed to process even higher amount of data with a computer. There are times the data stored in the hard disk must be transferred to other places over a network, but the large quantity of data requires a lot of time to complete the data transmission over the network. To enable convenient transmission of large quantity of data, people would some times remove the built-in hard disk from the computer into a portable hard disk drive (HDD) particularly designed to protect the hard disk against damage by external force. Therefore, the hard disk removed from the computer can be more safely carried about and conveniently linked to other computers for data transmission.

An existing portable HDD generally includes a rectangular disk enclosure defining a receiving space for a built-in hard disk drive. There are slots provided on the disk enclosure corresponding to sockets on the hard disk, such that the sockets on the hard disk are accessible from outside of the disk enclosure for linking to a computer to provide the function of data transmission. However, the conventional portable HDD does not include any stand, and is usually horizontally positioned on a desk top or other suitable places to occupy a quite large working area. Some of the conventional portable HDDs are equipped with a separated upright stand. However, such separated stand is not convenient for carrying about and uneasy to assemble.

### SUMMARY OF THE INVENTION

A primary object of the present invention is to provide a portable hard disk drive (HDD) with pivotable support legs, whereby when the support legs are pivotally turned to an extended position, the portable HDD is supported by the support legs to stand upright without occupying a large working area.

Another object of the present invention is to provide a portable HDD that includes two pivotable support legs having simple structure, enabling the portable HDD with portable support legs to be produced at reduced manufacturing cost.

To achieve the above and other objects, the portable hard disk drive (HDD) with pivotable support legs according to a preferred embodiment of the present invention includes a disk enclosure having a built-in HDD and being formed from two case members connected via an upper and a lower connecting strip; two support legs in the form of two curved panels separately mounted to an outer side of a lower part of each of the two case members via an elastic element and a pivot shaft, the elastic elements providing an elastic force to pivotally turn the two support legs outward from the lower parts of the two case members to an extended position; and a push button assembly provided on the lower connecting strip to normally hold the two support legs to a closed position. When the push button assembly is pushed, the two support legs are outward pushed by the elastic elements to the extended position, allowing the whole disk enclosure to stand upright.

Wherein, the two elastic elements connecting the support legs to the case members are torsional springs.

In an operable embodiment, each of the two case members is provided near an upper edge of the lower part with a transverse row of spaced through holes, each of which has a curled edge, and each of the two support legs has a curled upper edge. The two supporting legs are separately mounted to the outer sides of the two case members by aligning the upper curled edges of the supporting legs with the curled edges of the transverse row of spaced through holes, and extending the pivot shafts through the aligned curled edges and the two elastic elements.

In an operable embodiment, the upper and the lower edges of the two case members are inward bent and provided with a plurality of retaining sections for associating with two lateral edges of the upper and the lower connecting strip. And, the upper and the lower connecting strip are provided with a plurality of heat radiation apertures.

In a preferred embodiment, two end caps are separately connected to two opposite open ends defined between the two case members. One of the two end caps is provided with a plurality of heat radiation apertures; and the other end cap is provided at one side with a slot corresponding to a hard disk flat cable, and at the other side with a plurality of sockets for connecting with signal transmission cables and a power cord.

In a most preferred embodiment, the push button assembly includes a fixing member, an elastic element, and a push-button element. The fixing member has two perpendicularly downward extended sidewalls, and is fitted in a middle opening formed on the lower connecting strip. The push-button element is locked to the fixing member using a screw with the elastic element disposed between the fixing member and the push-button element.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a portable HDD with pivotable support legs according to a preferred embodiment of the present invention;

FIG. 2 an exploded view of FIG. 1;

FIG. 3 is an assembled bottom perspective view of the portable HDD of the present invention with a push button assembly for normally holding the pivotable support legs to a closed position;

FIG. 3A is an enlarged view of the encircled area of FIG. 3;

FIG. 4 is another assembled bottom perspective view of the portable HDD of the present invention showing a force is applied to push the push button assembly;

FIG. 4A is an enlarged view of the encircled area of FIG. 4;

FIG. 5 shows the pivotable support legs of the portable HDD of the present invention are sprung outward by two torsional springs to an extended position when the push button assembly is pushed;

FIG. 6 is a fragmentary sectioned side view of FIG. 3;

FIG. 7 is a fragmentary sectioned side view showing the push button is pushed;

FIG. 8 is a fragmentary sectioned side view showing the pivotable support legs of the present invention being turned to the extended position; and

FIG. 9 is a top perspective view of the portable HDD of the present invention with the pivotable support legs in the extended position.

### DETAILED DESCRIPTION OF THE PREFERRED EMBODIMENTS

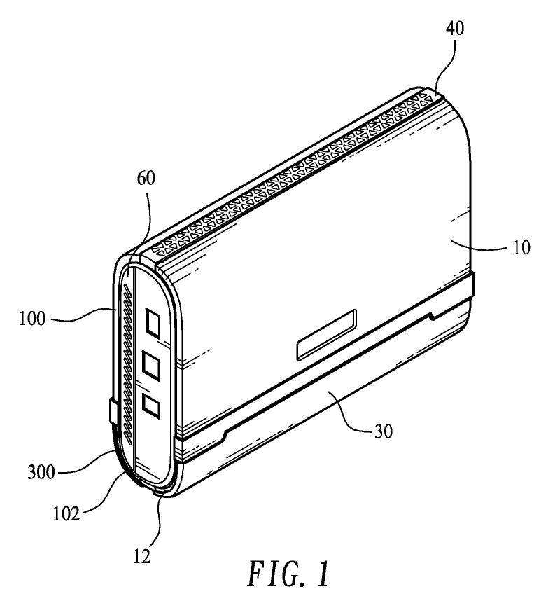

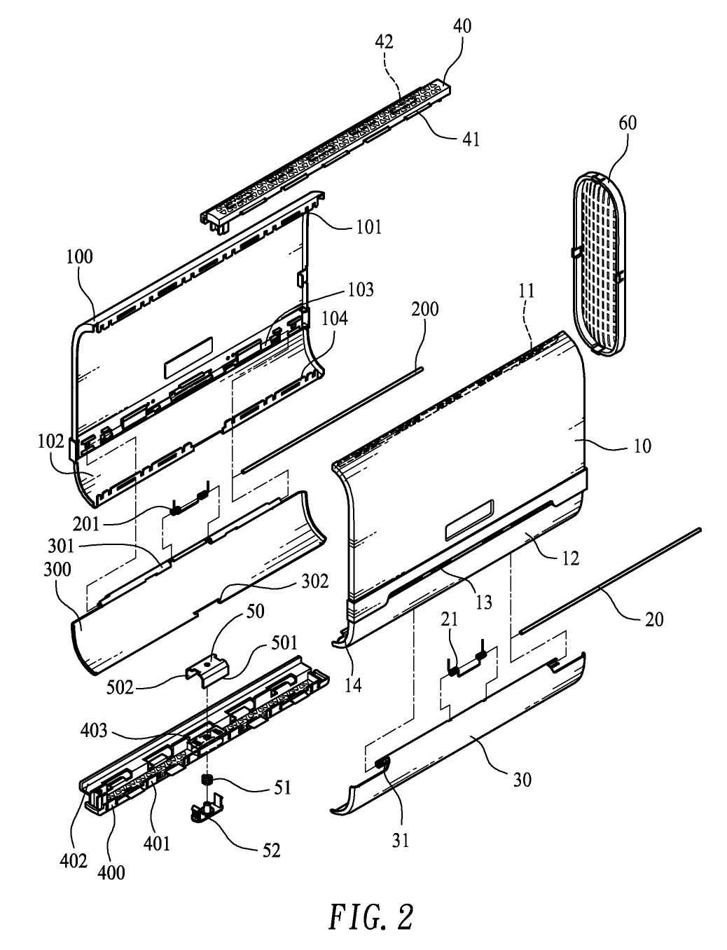

Please refer to FIGS. 1 and 2 that are assembled and exploded perspective views, respectively, of a portable hard disk drive (HDD) with pivotable support legs according to a preferred embodiment of the present invention. The portable HDD includes a disk enclosure having a built-in hard disk and formed from a first case member 10 and a second case member 100.

In the preferred embodiment, the first case member 10 is provided near a lower side with a transverse row of spaced through holes, each of which is provided with a curled edge 13, and a support leg 30 is mounted to an outer side of a lower part 12 of the first case member 10 below the transverse row of through holes. Similarly, the second case member 100 is provided near a lower side with a transverse row of spaced through holes, each of which is provided with a curled edge 103, and a support leg 300 is mounted to an outer side of a lower part 102 of the second case member 100 below the transverse row of through holes. The support legs 30, 300 are respectively provided on their upper end with curled edges 31, 301 adapted to engage with the spaces between the curled edges 13, 103 of the transverse row of spaced through holes on the first and the second case member 10, 100. Two elastic elements 21, 201 are respectively mounted between the curled edges 13 and 31 and the curled edges 103 and 301, and two pivot shafts 20, 200 are respectively extended through the aligned curled edges 13 and 31 and the aligned curled edges 103 and 301, so that the support legs 30, 300 are pivotally turnably connected to the outer side of the first and the second case member 10, 100 via the pivot shaft 20, 200, respectively.

In the illustrated preferred embodiment, the support legs 30, 300 are two curved panels, and the two elastic elements 21, 201 are torsional springs. When the support legs 30, 300 have been assembled to the outer side of the lower parts 12, 102, the elastic elements 21, 201 are in an elastically tensional state to normally push the two support legs 30, 300 outward from the lower parts 12, 102 of the first and second case members 10, 100, so that the portable HD drive is upright supported on the two support legs 30, 300.

In an operable embodiment of the present invention, the first and the second case 10, 100 respectively have inward bent upper and lower edges. The inward bent upper and lower edges of the first case member 10 include a plurality of retaining sections 11, 14, respectively; and the inward bent upper and lower curled edges of the second case member 100 include a plurality of retaining sections 101, 104. The portable HDD of the present invention further includes an upper and a lower connecting strip 40 and 400 located between and connected to the upper edges of and the lower edges of the first and the second case member 10, 100, respectively. The upper connecting strip 40 is provided along two lateral edges with hooking sections 41, 42 corresponding to the retaining sections 11, 101 on upper edges of the first and the second case member 10, 100; and the lower connecting strip 400 is provided along two lateral edges with hooking sections 401, 402 corresponding to the retaining sections 14, 104 on the lower edges of the first and the second case member 10, 100. The upper connecting strip 40 is connected to and between the inward bent upper edges of the first and the second case member 10, 100 by engaging the hooking sections 41 and 42 with the retaining sections 11, 101; and the lower connecting strip 400 is connected to and between the inward bent lower edges of the first and the second case member 10, 100 by engaging the hooking sections 401 and 402 with the retaining sections 14, 104. With these arrangements, the portable HDD of the present invention is structurally strong for use.

The lower connecting strip 400 is provided at a predetermined position with a receiving space 403 for receiving a push button assembly 5 therein. The push button assembly 5 includes a fixing member 50, an elastic element 51, and a push-button element 52. The fixing member 50 has two perpendicularly downward extended sidewalls 501, 502, and is fitted in the receiving space 403. The push-button element 52 is locked to a lower side of the fixing member 50 using a screw with the elastic element 51 located between the fixing member 50 and the push-button element 52 to complete the push button assembly 5.

The two support legs 30, 300 are provided at respective lower middle portion with an inward recessed locking section 32, 302, with which the two downward extended sidewalls 501, 502 of the fixing member 50 are normally engaged, so that the support legs 30, 300 are prevented from being sprung outward by the elastic elements 21, 201 to thereby fixedly bear against the outer side of the lower parts 12, 102 of the first and the second case member 10, 100 in a closed position.

In a preferred embodiment of the present invention, the upper and the lower connecting strip 40, 400 are provided with a plurality of heat radiation apertures, via which heat produced by the built-in hard disk in the disk enclosure during operation thereof can be well dissipated. Therefore, the portable HDD of the present invention provides good heat dissipation effect.

Please refer to FIGS. 1, 2, and 3. In the preferred embodiment of the present invention, two open ends defined between the first and the second case member 10, 100 are covered by an end cap 60 each. One of the two end caps 60 is provided with a plurality of heat radiation apertures to enhance the dissipation of heat produced by the hard disk in the portable HDD. The other end cap 60 is provided at one side with a slot corresponding to a hard disk flat cable, and at another side with a plurality of sockets for connecting with signal transmission cables and a power cord.

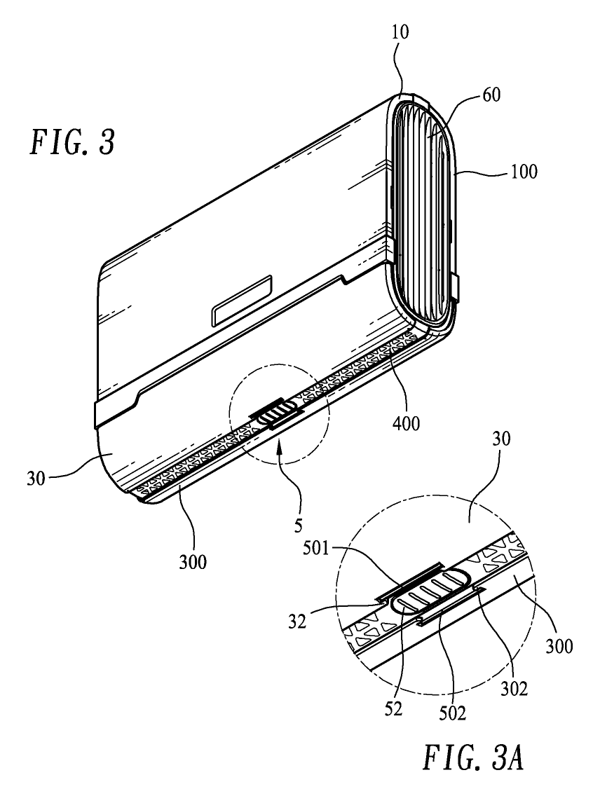

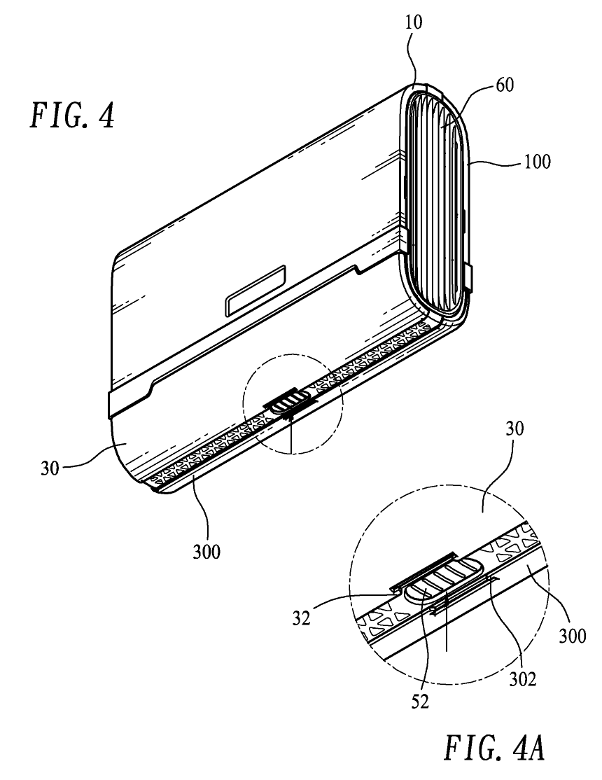

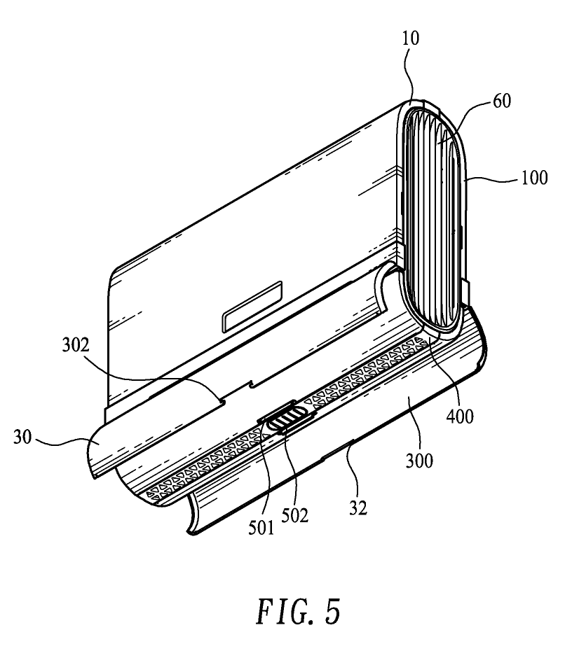

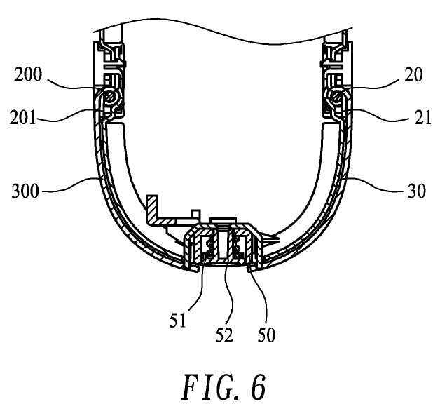

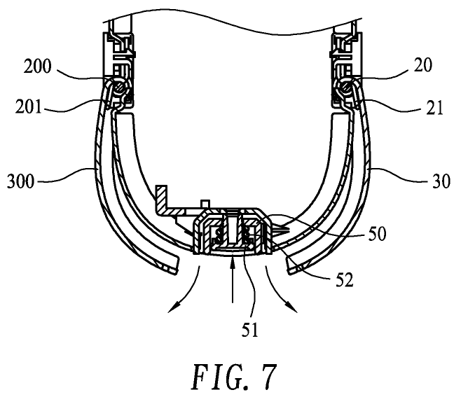

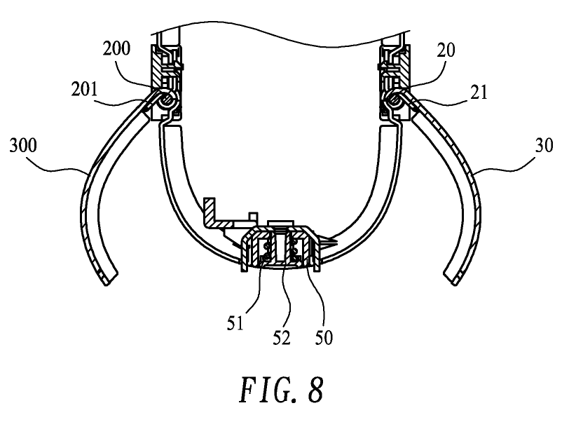

Please refer to FIGS. 3 through 8. With the above arrangements, a hard disk may be mounted in the portable HDD of the present invention. To use the portable HDD, a user may push the push-button element 52 of the push button assembly 5, so that the two sidewalls 501, 502 of the fixing member 51 are forced to retract and thereby disengaged from the locking sections 32, 302 on the two support legs 30, 300 that are currently bearing against two outer sides of the portable HDD. At this point, the elastic elements 21, 201 provide a restoring force to push the two support legs 30, 300 outward to an extended position, enabling the portable HDD to stand in an upright position without occupying a large space.

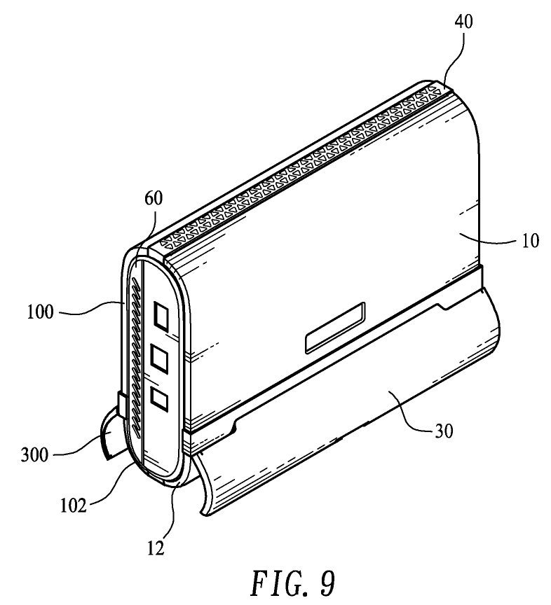

FIG. 9 shows the portable HDD of the present invention with the two support legs thereof pivotally turned outward to support the portable HDD in an upright position.

The present invention has simple structure and is convenient for use. With the elastic elements 21, 201 and the push button assembly 5, the two pivotable support legs for the portable HDD of the present invention can be easily turned between the closed position and the extended position.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A portable hard disk drive with pivotable support legs, comprising a disk enclosure having a built-in hard disk drive (HDD), the disk enclosure being formed from two case members connected at upper and lower edges via an upper and a lower connecting strip, respectively; two support legs in the form of two curved panels separately mounted to an outer side of a lower part of each of the two case members via an elastic element and a pivot shaft, the elastic elements normally providing an elastic force to push the two support legs outward from the lower parts of the two case members to an extended position; and a push button assembly provided on the lower connecting strip to normally hold the two support legs to a closed position.

2. The portable hard disk drive with pivotable support legs as claimed in claim 1, wherein each of the two case members is provided near an upper edge of the lower part with a transverse row of spaced through holes, each of which has a curled edge, and each of the two support legs has a curled upper edge; and the two supporting legs being separately mounted to the outer sides of the two case members by aligning the upper curled edges of the supporting legs with the curled edges of the transverse row of spaced through holes, and extending the pivot shafts through the aligned curled edges and the two elastic elements.

3. The portable hard disk drive with pivotable support legs as claimed in claim 1, wherein the upper and the lower edges of the two case members are inward bent and provided with a plurality of retaining sections for associating with two lateral edges of the upper and the lower connecting strip; and wherein the upper and the lower connecting strip are provided with a plurality of heat radiation apertures.

4. The portable hard disk drive with pivotable support legs as claimed in claim 1, further comprising two end caps separately connected to two opposite open ends defined between the two case members; one of the two end caps being provided with a plurality of heat radiation apertures, and the other end cap being provided at one side with a slot corresponding to a hard disk flat cable, and at the other side with a plurality of sockets for connecting with signal transmission cables and a power cord.

5. The portable hard disk drive with pivotable support legs as claimed in claim 1, wherein the push button assembly includes a fixing member, an elastic element, and a push-button element; the fixing member having two perpendicularly downward extended sidewalls, and being fitted in a middle opening formed on the lower connecting strip; and the push-button element being locked to the fixing member using a screw with the elastic element disposed between the fixing member and the push-button element.
